(19) United States
(12) Patent Application Publication
(10) Pub. No.: US 2020/0090991 A1
(43) Pub. Date: Mar. 19, 2020

(54) Method Of Forming Via With Embedded Barrier

(71) Applicant: Applied Materials, Inc., Santa Clara, CA (US)

(72) Inventors: Sang Ho Yu, Cupertino, CA (US); Seshadri Ganguli, Sunnyvale, CA (US)

(21) Appl. No.: 16/564,451

(22) Filed: Sep. 9, 2019

Related U.S. Application Data
(60) Provisional application No. 62/731,528, filed on Sep. 14, 2018.

(51) Int. Cl. H01L 21/768; H01L 23/522; H01L 23/532

(52) U.S. Cl. CPC H01L 21/76871; H01L 23/5226; H01L 23/53266; H01L 21/76877; H01L 23/5329; H01L 21/76816; H01L 23/53238

(57) ABSTRACT

Methods for forming barrier/seed layers for interconnect structures are provided. More specifically, methods of depositing a film on a substrate having an opening formed in a first surface of the substrate, the opening having a sidewall with a dielectric surface and a bottom with a conductive surface. A manganese-ruthenium film is formed in the opening in the first surface of the substrate on the conductive surface.

### CROSS-REFERENCE TO RELATED APPLICATIONS

This application claims priority to U.S. Provisional Application No. 62/731,528, filed Sep. 14, 2018, the entire disclosure of which is hereby incorporated by reference herein.

### TECHNICAL FIELD

Embodiments of the present disclosure pertain to the field of electronic device manufacturing and methods for device patterning. More particularly, embodiments of the disclosure provide methods for forming embedded barriers for interconnect structures.

### BACKGROUND

Semiconductor technology has advanced at a rapid pace and device dimensions have shrunk with advancing technology to provide faster processing and storage per unit space. As dimensions reach 7 nm, manufacturing challenges become more apparent. The combined thickness of barrier layers deposited in an opening prior to filling the opening (e.g. electroplating) to form an interconnect structure may result in reduced efficiency of the electroplating process.

Barrier layers are included in current processing schemes in order, for example, to prevent copper diffusion. The main contributor to via resistance is barrier layers, which can have a resistivity of greater than 350 μQ-cm.

Ruthenium has become a promising candidate as a seed layer for a copper interconnect. Ruthenium, however, by itself cannot be a copper barrier and barrier layers such as TaN/Ta are still needed prior to ruthenium deposition. Alternatively, copper-manganese, deposited for example by physical vapor deposition (PVD), self-aligned barrier schemes have also gained in popularity as a desirable approach to the barrier solution. These two schemes, however, each have manufacturability difficulties.

For CVD ruthenium, the deposition rate is very slow without oxygen as a reducing gas. The oxygen gas tends to oxidize the tantalum-based barrier layer, resulting in increased via resistance. Therefore, with TaN/Ta as a barrier, throughput with CVD ruthenium will be very slow. Additionally, deposition of ruthenium without oxygen also results in high carbon contaminated ruthenium films, increasing line/via resistance. A high resistivity ruthenium film is not adequate for a seed layer, which is the main merit of the ruthenium seed layer.

With respect to a Cu—Mn process (a physical vapor deposition, process), copper can diffuse into the oxide layer, especially low-K oxide, during deposition, causing reliability issues.

Accordingly, there is a need for methods of forming barrier/seed layers for interconnect structures.

### SUMMARY

Methods and devices to manufacture interconnect structures are described. In one or more embodiments, a method of depositing a film comprises positioning a substrate in a processing chamber, the substrate having an opening in a first surface, the opening having a sidewall with a dielectric surface and a bottom with a conductive surface. A manganese-ruthenium film is formed by exposing the substrate to one or more metal precursor comprising one or more of manganese (Mn) or ruthenium (Ru) to form a manganese-ruthenium film in the opening in the first surface of the substrate on the conductive surface. A conductive material is deposited on the manganese-ruthenium film to fill the opening in the first surface of the substrate forming a via.

In one or more embodiments, a method of processing a substrate having an opening formed in a first surface of the substrate, the opening having a sidewall and a bottom is described. The method comprises forming a first manganese-ruthenium film on a dielectric surface of the sidewall and on a conductive surface of the bottom of the opening by exposing the substrate to one or more metal precursor comprising one or more of manganese or ruthenium. A second manganese-ruthenium film is formed on the first manganese-ruthenium film by exposing the substrate to one or more metal precursor comprising one or more of manganese or ruthenium. A third manganese-ruthenium film is formed on the second manganese-ruthenium film by exposing the substrate to one or more metal precursor comprising one or more of manganese or ruthenium. A conductive material is deposited on the third manganese-ruthenium film to fill the opening forming a via.

In one or more embodiments, an electronic device is described. The electronic device comprises a substrate having a feature formed in a first surface, the feature extending into the substrate from the first surface and having a sidewall with a dielectric surface and a bottom with a conductive surface. A manganese-ruthenium film is in the bottom of the feature on the conductive surface. A conductive material is on the manganese-ruthenium film filling the feature to form a via.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a flow process diagram of one embodiment of a method of forming a thin film according to embodiments described herein;

FIG. 2A illustrates a cross-sectional view of a substrate according to one or more embodiments;

FIG. 2B illustrates a top view of a substrate according to one or more embodiments;

FIG. 3A illustrates a cross-sectional view of a substrate according to one or more embodiments;

FIG. 3B illustrates a cross-sectional view of a substrate according to one or more embodiments;

FIG. 3C illustrates a top view of a substrate according to one or more embodiments;

FIG. 4A illustrates a cross-sectional view of a substrate according to one or more embodiments;

FIG. 4B illustrates a top view of a substrate according to one or more embodiments;

FIG. 5 is a block diagram of a process chamber in accordance with one or more embodiments of the disclosure; and

FIG. 6 a schematic view of a cluster tool in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Methods for forming barrier/seed layers for interconnect structures are provided. As used herein, the term “barrier/seed layer” refers to any layer comprising a seed layer deposited atop a barrier layer, or a layer comprising a barrier layer material and a seed layer material, wherein the barrier and seed layer materials may be deposited in any suitable manner, such as homogeneously, graded, or the like, within the layer to facilitate both barrier layer and seed layer properties. The methods of one or more embodiments advantageously reduce via resistance, improve scalability, and improve reliability.

The methods of one or more embodiments may be utilized with any device nodes, but may be particularly advantageous in device nodes of about 7 nm or less. Additionally, the methods of one or more embodiments may be utilized with any type of interconnect structures or material, but may be particularly advantageous with interconnect structures including copper (Cu).

As used in this specification and the appended claims, the term “substrate” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus for example, where a film/layer or partial film/layer has been deposited onto a substrate surface, the exposed surface of the newly deposited film/layer becomes the substrate surface.

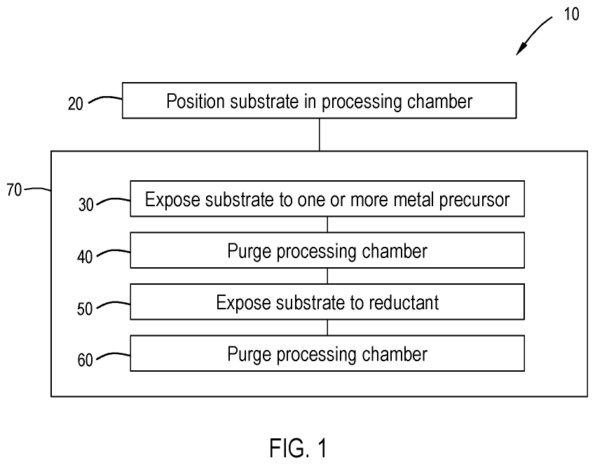

FIG. 1 depicts a flow diagram of a method 10 of depositing a film in accordance with one or more embodiments of the present disclosure. With reference to FIG. 1, the method 10 comprises a deposition cycle 70. The method 10 begins at operation 20 by providing or positioning a substrate in a processing chamber.

At operation 30, the substrate is exposed in the processing chamber to one or more metal precursor comprising one or more of manganese (Mn) or ruthenium (Ru) to form a manganese-ruthenium film.

At operation 40, which is optional, the processing chamber is purged of the one or more metal precursor. Purging can be accomplished with any suitable gas that is not reactive with the substrate, film on the substrate, and/or processing chamber walls. Suitable purge gases include, but are not limited to, N₂, He, and Ar. The purge gas may be used to purge the processing chamber of the one or more metal precursor, and/or the reductant. In some embodiments, the same purge gas is used for each purging operation. In other embodiments, a different purge gas is used for the various purging operations.

At operation 50, which is optional, the substrate is exposed to a reducing agent to react with the manganese-ruthenium film. In one or more embodiments, the reducing agent is selected from one or more of molecular hydrogen (H₂), ammonia (NH₃), hydrazine (N₂H₄), silane (SiH₄), disilane (Si₂H₆), hydrocarbon compounds, hydrogen incorporated compounds, or direct/remote plasma.

At operation 60, which is optional, the processing chamber is purged of the reductant. Purging can be accomplished with any suitable gas that is not reactive with the substrate, film on the substrate, and/or processing chamber walls. Suitable purge gases include, but are not limited to, molecular nitrogen (N₂), helium (He), and argon (Ar). The purge gas may be used to purge the processing chamber of the one or more metal precursor, and/or the reductant. In some embodiments, the same purge gas is used for each purging operation. In other embodiments, a different purge gas is used for the various purging operations.

In addition to selectivity improvement, in one or more embodiments, using the one or more metal precursor comprising one or more of ruthenium or manganese advantageously offers unique film properties for the via that is formed. For example, the vias prepared according to the methods of one or more embodiments have a low resistivity. More specifically, the resistivity of the manganese-ruthenium film of some embodiments is less than or equal to 250, 225, 200, 175, 150, 125 or 100 μΩ-cm. In one or more embodiments, the resistivity of the manganese-ruthenium film after annealing is less than or equal to 250, 225, 200, 175, 150, 125 or 100 μΩ-cm.

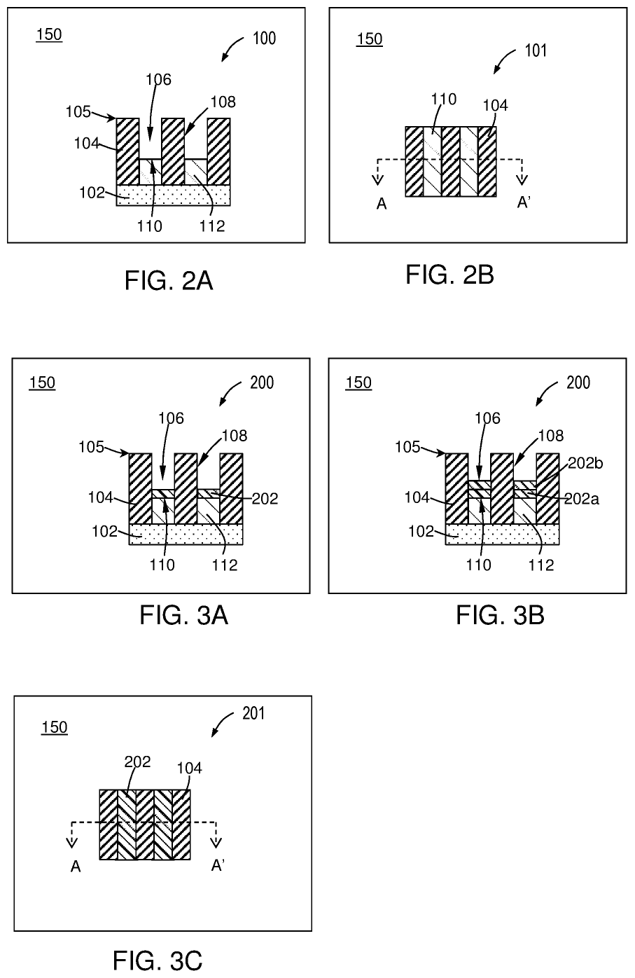

FIGS. 2A-4B provide cross-sectional views and top views according to one or more embodiments. In one or more embodiments, the substrate 102 may be patterned according to any of the techniques known to those of skill in the art. FIG. 2A is a cross-sectional view 100 of a substrate 102 according to one or more embodiments. FIG. 2B is a top view 101 of the substrate 102 according to one or more embodiments. With reference to FIGS. 2A and 2B, in one or more embodiments, a substrate 102 is provided and placed in a processing chamber 150. As used in this specification and the appended claims, the term “provided” means that the substrate is made available for processing (e.g., positioned in a processing chamber). The substrate 102 has an opening 106 in a first surface 105, the opening 106 having a sidewall 108 with a dielectric surface 104 and a bottom 112 with a conductive surface 110.

In one or more embodiments, the sidewall 108 has a dielectric surface 104. As used herein, the term “dielectric” refers to an electrical insulator material that can be polarized by an applied electric field. In one or more embodiments, the dielectric surface 104 comprises a dielectric material including, but not limited to, oxides, e.g., SiO₂, Ta₂O₅, Al₂O₃, nitrides, e.g., Si₃N₄, and barium strontium titanate (BST). The skilled artisan will recognize that the various films and layers may not have a stoichiometric amount of the listed elements and that use of chemical formulae indicates an approximate stoichiometric relationship. For example, a silicon oxide (SiO₂) film comprises silicon and oxygen atoms in an approximate one-to-two ratio, respectively. In one or more embodiments, the dielectric material comprises silicon dioxide (SiO₂). In some embodiments, the dielectric material is non-stoichiometric relative to the ideal molecular formula. For example, in some embodiments, the dielectric material includes, but is not limited to, oxides (e.g., silicon oxide, tantalum oxide, aluminum oxide), nitrides (e.g., silicon nitride (SiN)), carbides (e.g. silicon carbide (SiC)), oxycarbides (e.g. silicon oxycarbide (SiOC)), oxynitrocarbides (e.g. silicon oxycarbonitride (SiNCO)), and barium strontium titanate (BST).

In one or more embodiments, the conductive surface 112 comprises a metal selected from one or more of cobalt (Co), copper (Cu), nickel (Ni), ruthenium (Ru), manganese (Mn), silver (Ag), gold (Au), platinum (Pt), iron (Fe), molybdenum (Mo), rhodium (Rh), titanium (Ti), tantalum (Ta), silicon (Si), or tungsten (W). In other embodiments, the conductive surface 112 comprises a metal selected from one or more of copper (Cu), cobalt (Co), tungsten (W), or ruthenium (Ru). In one or more embodiments, the conductive surface 112 is one or more of a metal, a metal carbide, a metal nitride, or a metal silicide. In one or more specific embodiments, the conductive surface 112 comprises or consists essentially of copper (Cu). As used in this specification and the appended claims, the term “consists essentially of” means that the subject film or composition is greater than or equal to about 95%, 98%, 99% or 99.5% of the stated species.

FIGS. 3A and 3B are cross-sectional views 200 of a substrate 102 according to one or more embodiments. FIG. 3C is a top view 201 of a substrate 102 according to one or more embodiments. According to the method of one or more embodiments, the substrate 102 positioned in processing chamber 150 is exposed to one or more metal precursor comprising one or more of manganese (Mn) or ruthenium (Ru) to form a manganese-ruthenium film 202 in the opening 106 in the first surface 105 of the substrate 102 on the conductive surface 112.

In one or more embodiments, a manganese-ruthenium film 202 is formed on the sidewall(s) 108 and the bottom 110 of the opening 106. The manganese-ruthenium film 202 comprises manganese (Mn) and ruthenium (Ru). In some embodiments, the manganese-ruthenium film 202 may be a single layer having uniform or non-uniform composition through a thickness of the layer. In other embodiments, the manganese-ruthenium film 202 may be formed from multiple layers deposited atop each other. For example, FIG. 3A depicts the manganese-ruthenium film 202 formed as a single layer. FIG. 3B depicts the manganese-ruthenium film 202 formed as two layers, a first layer 202a and a second layer 202b deposited atop the first layer 202a.

In one or more embodiments, the manganese-ruthenium film 202 may comprise a barrier layer comprising predominantly Mn and a seed layer comprising predominantly Ru. Alternatively, in one or more embodiments, the manganese-ruthenium film 202 may comprise a barrier layer material comprising predominantly Mn and a seed layer material comprising predominantly Ru, wherein the barrier and seed layer materials are deposited throughout the thickness of the manganese-ruthenium film 202. For example, the manganese-ruthenium film 202 may comprise about 10-50 percent, or more, of Mn proximate an interface between the manganese-ruthenium film 202 and the sidewall(s) 108 or the bottom 110 with a conductive surface 112 and may comprise substantially Ru (e.g., about 50 percent or more) proximate an opposing surface of the manganese-ruthenium film 202.

The manganese-ruthenium film 202 may have a graded concentration of the barrier layer (e.g., Mn) and seed layer (e.g., Ru) materials between the interface and the opposing surface of the manganese-ruthenium film 202. For example, the barrier layer material may decrease in concentration from the interface to the opposing surface of the manganese-ruthenium film 202 and the seed layer material may increase in concentration from the interface to the opposing surface of the manganese-ruthenium film 202. Additionally, the manganese-ruthenium film 202 may have a first composition in a first portion of the manganese-ruthenium film 202 proximate the interface between the manganese-ruthenium film 202 and the substrate 102, a second composition in a second portion of the manganese-ruthenium film 202 proximate the interface between the manganese-ruthenium film 202 and the opening 106, with a transitional region disposed (not shown) therebetween. In one or more embodiments, when moving from the first portion towards the second portion of the transitional region (e.g., from adjacent the substrate 102 towards the opening 106), the concentration of the barrier layer material may decrease and the concentration of the seed layer material may increase.

A “conductive surface” as used herein, refers to a material that conducts electricity. Conductive materials include conductor and semiconductor materials. A “non-conductive surface” as used herein, refers to a material that acts as an insulator.

In one or more embodiments, the one or more metal precursor comprises one or more of manganese (Mn) or ruthenium (Ru). In some embodiments, the metal precursor comprises manganese, and the substrate 102 is exposed to a manganese precursor. The processing chamber 150 is then purged of the manganese precursor, and the substrate 102 is exposed to a metal precursor comprising ruthenium. The processing chamber 150 is then purged of the ruthenium precursor. In other embodiments, the metal precursor comprises ruthenium, and the substrate 102 is exposed to the ruthenium precursor. The processing chamber 150 is then purged of the ruthenium precursor, and the substrate 102 is exposed to a metal precursor comprising manganese. The processing chamber 150 is then purged of the ruthenium precursor. In other embodiments, the metal precursor comprises a binuclear ruthenium manganese precursor. As used herein, the term “binuclear” refers to a molecular composition having two nuclei. In one or more embodiments, the term “binuclear” means that both ruthenium and manganese are present in the precursor.

As used in this specification and the appended claims, the terms “precursor”, “reactant”, “reactive gas” and the like are used interchangeably to refer to any gaseous species that can react with the substrate surface.

The manganese-ruthenium film 202 may be formed by CVD, ALD, or PVD processes.

In one or more embodiments, exposing the substrate 102 to one or more metal precursor comprising one or more of ruthenium or manganese to form a manganese-ruthenium film 202 involves an atomic layer deposition (ALD), which employs sequential, self-limiting surface reactions to form the manganese-ruthenium film 202. In one or more embodiments, one or more metal precursor comprising one or more of ruthenium or manganese are introduced into a processing chamber, where the one or more metal precursor reacts with the surface of the substrate 102, and the conductive surface 112 of the opening 106 to form a manganese-ruthenium film 202. In other embodiments, one or more metal precursor comprising one or more of ruthenium or manganese are introduced into a processing chamber, where the one or more metal precursor partially reacts with the surface of the substrate 102, and the conductive surface 112 of the opening 106. Then, a reductant may be introduced to reduce the partially reacted one or more metal precursor to form a manganese-ruthenium film 202.

“Atomic layer deposition” or “cyclical deposition” as used herein refers to the sequential exposure of two or more reactive compounds to deposit a layer of material on a substrate surface. The substrate, or portion of the substrate, is exposed sequentially or separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially.

In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g. manganese precursor, ruthenium precursor, or a manganese-ruthenium precursor) is pulsed into the reaction zone followed by a first time delay. Next, a second precursor or compound B (e.g. reductant) is pulsed into the reaction zone followed by a second delay. During each time delay, a purge gas, such as argon, may be introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B, and purge gas is a cycle. A cycle can start with either compound A or compound B and continue the respective order of the cycle until achieving a film with the predetermined thickness.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The durations for each pulse/dose are variable and may be adjusted to accommodate, for example, the volume capacity of the processing chamber as well as the capabilities of a vacuum system coupled thereto. Additionally, the dose time of a process gas may vary according to the flow rate of the process gas, the temperature of the process gas, the type of control valve, the type of process chamber employed, as well as the ability of the components of the process gas to adsorb onto the substrate surface. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The metal precursor-containing process gas may be provided in one or more pulses or continuously. The flow rate of the metal precursor-containing process gas can be any suitable flow rate including, but not limited to, flow rates is in the range of about 1 to about 5000 sccm, or in the range of about 2 to about 4000 sccm, or in the range of about 3 to about 3000 sccm or in the range of about 5 to about 2000 sccm. The metal precursor can be provided at any suitable pressure including, but not limited to, a pressure in the range of about 5 mTorr to about 500 Torr, or in the range of about 100 mTorr to about 500 Torr, or in the range of about 5 Torr to about 500 Torr, or in the range of about 50 mTorr to about 500 Torr, or in the range of about 100 mTorr to about 500 Torr, or in the range of about 200 mTorr to about 500 Torr.

The period of time that the substrate is exposed to the one or more metal precursor-containing process gas may be any suitable amount of time necessary to allow the metal precursor to form an adequate nucleation layer atop the conductive surface of the bottom of the opening. For example, the process gas may be flowed into the process chamber for a period of about 0.1 seconds to about 90 seconds. In some time-domain ALD processes, the metal precursor-containing process gas is exposed the substrate surface for a time in the range of about 0.1 sec to about 90 sec, or in the range of about 0.5 sec to about 60 sec, or in the range of about 1 sec to about 30 sec, or in the range of about 2 sec to about 25 sec, or in the range of about 3 sec to about 20 sec, or in the range of about 4 sec to about 15 sec, or in the range of about 5 sec to about 10 sec.

In some embodiments, an inert carrier gas may additionally be provided to the process chamber at the same time as the metal precursor-containing process gas. The carrier gas may be mixed with the metal precursor-containing process gas (e.g., as a diluent gas) or separately and can be pulsed or of a constant flow. In some embodiments, the carrier gas is flowed into the processing chamber at a constant flow in the range of about 1 to about 10000 sccm. The carrier gas may be any inert gas, for example, such as argon, helium, neon, combinations thereof, or the like. In one or more embodiments, a metal precursor-containing process gas is mixed with argon prior to flowing into the process chamber.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In one or more embodiments, exposing the substrate 102 to one or more metal precursor comprising one or more of manganese or ruthenium to deposit a manganese-ruthenium film 202 utilizes a chemical vapor deposition (CVD) process, which involves co-flowing one or more metal precursor comprising one or more of ruthenium or manganese and, optionally, a reductant, to form the manganese-ruthenium film 202. As will be understood by the skilled artisan, “chemical vapor deposition” refers to a process in which a substrate surface is exposed to precursors and/or co-reagents simultaneously or substantially simultaneously. As used herein, “substantially simultaneously” refers to either co-flow or where there is overlap of exposures of the precursors so that the reactive species are able to react in the gas phase.

Reaction conditions, including temperature, pressure, processing time, the substrate surface(s), and the organic platinum group metal precursors can be selected to obtain the desired level of selective deposition of the manganese-ruthenium film 202 on the conductive surface 112 in the opening 106.

The temperature of the substrate during deposition can be controlled, for example, by setting the temperature of the substrate support or susceptor. In some embodiments the conductive substrate is held at a temperature less than or equal to about 450° C., including a temperature less than about 400° C., less than about 350° C., less than about 300° C., less than about 250° C., less than about 200° C., less than about 150° C., or less than about 100° C.

In one or more embodiments, the substrate 102 is exposed to the one or more metal precursor comprising one or more of ruthenium or manganese for a period of time in the range of about 1 minute to about 30 minutes, including about 1 minute, about 5 minutes, about 10 minutes, about 15 minutes, about 20 minutes, about 25 minutes, and about 30 minutes.

In one or more embodiments, the manganese-ruthenium film 202 is substantially free of manganese oxide or ruthenium oxide.

In one or more embodiments, a binuclear ruthenium manganese precursor may be used to deposit the manganese-ruthenium film 202 (or an alternate deposition of Ru and Mn). A binuclear ruthenium manganese precursor is a compound comprising both ruthenium and manganese atoms. In one or more embodiments, the manganese-ruthenium film 202 is annealed at a temperature of less than or equal to 500° C. Without intending to be bound by theory, it is thought that annealing the manganese-ruthenium film 202 will drive the manganese out of the ruthenium and into the dielectric surface 104. In one or more embodiments, substantially all of the manganese is driven out of manganese-ruthenium film 202 into the dielectric surface 104. Manganese has high affinity for oxygen and may react with the dielectric surface 104 to form manganese-silicate. Manganese-silicate can form a good barrier to moisture, oxygen, and copper diffusion. As used herein, the term “substantially all” means that the manganese-ruthenium film has less than 30.0 wt % manganese remaining after annealing, including less than 25.0 wt. %, less than 20.0 wt. %, less than 15.0 wt. %, less than 10.0 wt. %, and less than 5.0 wt. %

In one or more embodiments, the deposited the manganese-ruthenium film 202 has mainly manganese as metal and not as manganese-oxide and/or manganese nitride.

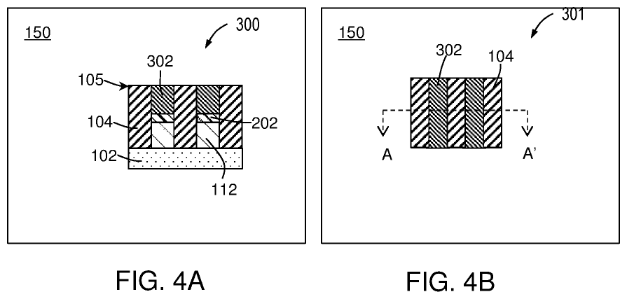

FIG. 4A is a cross-sectional view 300 of a substrate 102 according to one or more embodiments. FIG. 4B is a top-sectional view 301 of a substrate 102 according to one or more embodiments. According to the method of one or more embodiments, a conductive material 302 is deposited on the manganese-ruthenium film 202 to fill the opening 106 in the first surface 105 of the substrate 102 positioned in processing chamber 150 to form a via.

A “conductive material” as used herein, refers to a material that conducts electricity. Conductive materials include conductor and semiconductor materials.

A “non-conductive material” as used herein, refers to a material that acts as an insulator.

In one or more embodiments, the conductive material 302 comprises a metal selected from one or more of cobalt (Co), copper (Cu), nickel (Ni), ruthenium (Ru), manganese (Mn), silver (Ag), gold (Au), platinum (Pt), iron (Fe), molybdenum (Mo), rhodium (Rh), titanium (Ti), tantalum (Ta), silicon (Si), or tungsten (W). In one or more specific embodiments, the conductive material comprises one or more of copper (Cu), cobalt (Co), tungsten (W), or ruthenium (Ru).

One or more embodiments are directed to an electronic device. The electronic device comprises a substrate having a feature formed in a first surface, the feature extending into the substrate from the first surface and having a sidewall with a dielectric surface and a bottom with a conductive surface; a manganese-ruthenium film in the bottom of the feature on the conductive surface; and a conductive material on the manganese-ruthenium film filling the feature to form a via. In one or more embodiments, the conductive material and the conductive surface independently comprises one or more of copper (Cu), cobalt (Co), tungsten (W), or ruthenium (Ru). The dielectric surface may comprises comprises one or more of oxides, carbon doped oxides, porous silicon dioxide (SiO₂), silicon oxide (SiO), silicon nitride (SiN), carbides, oxycarbides, nitrides, oxynitrides, oxycarbonitrides, carbonitrides, polymers, phosphosilicate glass, fluorosilicate (SiOF) glass, or organosilicate glass (SiOCH).

As used herein, the term “feature” or “topographic feature” refers to one or more of an opening, a trench, a via, a peak, or the like.

In a second aspect of the disclosure, a ruthenium capping layer is deposited on a wafer having no features, only exposed metal (e.g. copper) or dielectric on the surface of the wafer. In one or more embodiments, the capping layer is formed by exposing a substrate to a selective manganese precursor (or selective binuclear ruthenium manganese precursor) followed by exposure to a selective ruthenium precursor to form a capping layer on the conductive metal only. In one or more embodiments, the thickness of the capping layer is in a range of about 10 Å to about 30 Å. In one or more embodiments, there is substantially no deposition on the dielectric.

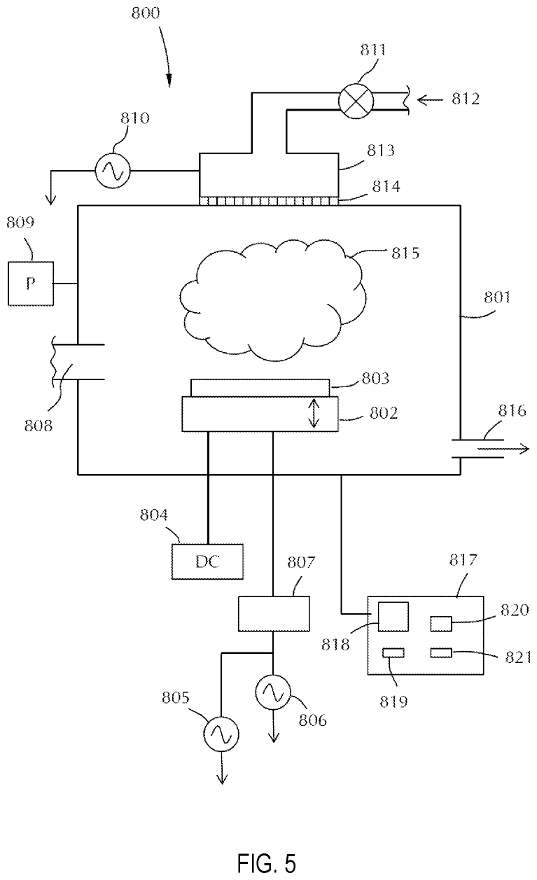

FIG. 5 shows a block diagram of a plasma system 800 to perform at least some of the method of one or more embodiments. The plasma system 800 illustrated has a processing chamber 801. A movable pedestal 802 to hold a substrate 803 that has been positioned in processing chamber 801. Pedestal 802 can comprise an electrostatic chuck (“ESC”), a DC electrode embedded into the ESC, and a cooling/heating base. In an embodiment, pedestal 802 acts as a moving cathode. In an embodiment, the ESC comprises an Al₂O₃ material, Y₂O₃, or other ceramic materials known to one of ordinary skill of electronic device manufacturing. A DC power supply 804 can be connected to the DC electrode of the pedestal 802. In some embodiments, the pedestal 802 includes a heater (not shown) that is capable of raising the temperature of the substrate to the first temperature. While an electrostatic chuck is illustrated as the pedestal 802, those skilled in the art will understand that this is merely exemplary and other pedestal types are within the scope of the disclosure.

In one or more embodiments, the manganese-ruthenium film is typically deposited utilizing a thermal deposition process. In such instances, a plasma and a heater are unnecessary. While a plasma and a heater are illustrated in FIG. 5, those skilled in the art will understand that this is merely exemplary and may not be required for the deposition methods of one or more embodiments.

As shown in FIG. 5, a substrate 803 can be loaded through an opening 808 and placed on the pedestal 802. Plasma system 800 comprises an inlet to input one or more process gases 812 through a mass flow controller 811 to a plasma source 813. A plasma source 813 comprising a showerhead 814 is coupled to the processing chamber 801 to receive one or more process gases 812 to generate plasma. Plasma source 813 is coupled to a RF power source 810. Plasma source 813 through showerhead 814 generates a plasma 815 in processing chamber 801 from one or more process gases 812 using a high frequency electric field. Plasma 815 comprises plasma particles, such as ions, electrons, radicals, or any combination thereof. In an embodiment, power source 810 supplies power from about 50 W to about 3000 W at a frequency from about 400 kHz to about 162 MHz to generate plasma 815.

A plasma bias power 805 is coupled to the pedestal 802 (e.g., cathode) via a RF match 807 to energize the plasma. In an embodiment, the plasma bias power 805 provides a bias power that is not greater than 1000 W at a frequency between about 2 MHz to 60 MHz, and in a particular embodiment at about 13 MHz. A plasma bias power 806 may also be provided, for example, to provide another bias power that is not greater than 1000 W at a frequency from about 400 kHz to about 60 MHz, and in a particular embodiment, at about 60 MHz. Plasma bias power 806 and plasma bias power 805 are connected to RF match 807 to provide a dual frequency bias power. In an embodiment, a total bias power applied to the pedestal 802 is from about 10 W to about 3000 W.

As shown in FIG. 5, a pressure control system 809 provides a pressure to processing chamber 801. The chamber 801 has one or more exhaust outlets 816 to evacuate volatile products produced during processing in the chamber. In an embodiment, the plasma system 800 is an inductively coupled plasma (ICP) system. In an embodiment, the plasma system 800 is a capacitively coupled plasma (CCP) system.

In some embodiments, a control system 817 is coupled to the processing chamber 801. The control system 817 comprises a processor 818, a temperature controller 819 coupled to the processor 818, a memory 820 coupled to the processor 818, and input/output devices 821 coupled to the processor 818. The memory 820 can include one or more of transitory memory (e.g., random access memory) and non-transitory memory (e.g., storage).

In one embodiment, the processor 818 has a configuration to control one or more of: exposing a substrate in the processing chamber to an aluminum precursor; purging of a substrate in the processing chamber, exposing a substrate in the processing chamber to an oxidant, or forming a thin film comprising less than or equal to about 150 monolayers of aluminum oxide on a substrate.

The control system 817 can be configured to perform at least some of the methods as described herein and may be either software or hardware or a combination of both. The plasma system 800 may be any type of high performance processing plasma systems known in the art, such as but not limited to an etcher, a cleaner, a furnace, or any other plasma system to manufacture electronic devices.

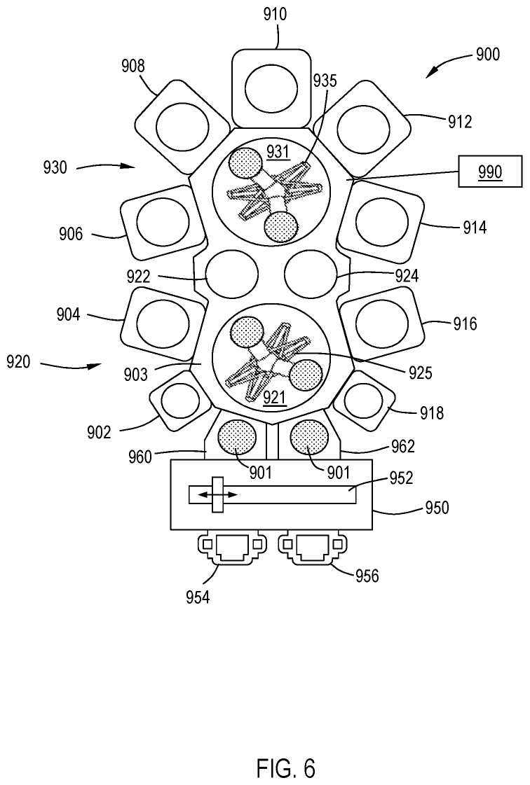

Some embodiments of the disclosure are directed to cluster tools 900, as shown in FIG. 6. The cluster tool 900 includes at least one central transfer station with a plurality of sides. A robot is positioned within the central transfer station and is configured to move a robot blade to each of the plurality of sides.

FIG. 6 shows a schematic diagram of an illustrative multiple chamber semiconductor processing tool, also referred to as a cluster tool or multi-cluster tool. The cluster tool 900 comprises a plurality of processing chambers 902, 904, 906, 908, 910, 912, 914, 916, and 918. The various processing chambers can be any suitable chamber including, but not limited to, a preclean chamber, a buffer chamber, transfer space(s), a wafer orienter/degas chamber, a cryo cooling chamber, and a transfer chamber. The particular arrangement of process chambers and components can be varied depending on the cluster tool and should not be taken as limiting the scope of the disclosure.

In the embodiment shown in FIG. 6, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of depositing a film, the method comprising:
positioning a substrate in a processing chamber, the substrate having an opening in a first surface, the opening having a sidewall with a dielectric surface and a bottom with a conductive surface; and
forming a manganese-ruthenium film by exposing the substrate to one or more metal precursor comprising one or more of manganese (Mn) or ruthenium (Ru) to form a manganese-ruthenium film in the opening in the first surface of the substrate on the conductive surface; and
depositing a conductive material on the manganese-ruthenium film to fill the opening in the first surface of the substrate forming a via.

2. The method of claim 1, wherein forming the manganese-ruthenium film comprises repeated exposures to the metal precursor to form a manganese-ruthenium film having a thickness in a range of about 10 Å to about 50 Å.

3. The method of claim 1, wherein the opening has an aspect ratio of height to width of at least 5:1.

4. The method of claim 1, wherein the conductive material is deposited by one or more of electroplating, atomic layer deposition (ALD), or chemical vapor deposition (CVD).

5. The method of claim 4, wherein the conductive material comprises one or more of copper (Cu), cobalt (Co), tungsten (W), or ruthenium (Ru).

6. The method of claim 1, wherein forming the manganese-ruthenium film comprises sequential exposure to the metal precursor and a reducing agent.

7. The method of claim 6, wherein the reducing agent comprises one or more of hydrogen (H₂), ammonia (NH₃), hydrazine (N₂H₄), silane (SiH₄), disilane (Si₂H₆), hydrocarbon compounds, or hydrogen incorporated compounds.

8. The method of claim 1, wherein during formation of the manganese-ruthenium film, the substrate is maintained at a temperature of less than or equal to about 450° C.

9. The method of claim 1, wherein the manganese-ruthenium film is substantially free of manganese oxide or ruthenium oxide.

10. The method of claim 1, wherein the metal precursor is a binuclear ruthenium manganese precursor.

11. The method of claim 1, further comprising annealing the substrate at a temperature of less than or equal to 500° C. prior to deposition of the conductive material.

12. The method of claim 11, wherein annealing the substrate further forms a ruthenium film.

13. A method of processing a substrate having an opening formed in a first surface of the substrate, the opening having a sidewall and a bottom, the method comprising:
forming a first manganese-ruthenium film on a dielectric surface of the sidewall and on a conductive surface of the bottom of the opening by exposing the substrate to one or more metal precursor comprising one or more of manganese or ruthenium;
forming a second manganese-ruthenium film on the first manganese-ruthenium film by exposing the substrate to one or more metal precursor comprising one or more of manganese or ruthenium;
forming a third manganese-ruthenium film on the second manganese-ruthenium film by exposing the substrate to one or more metal precursor comprising one or more of manganese or ruthenium; and
depositing a conductive material on the third manganese-ruthenium film to fill the opening forming a via.

14. The method of claim 13, wherein during formation of the first manganese-ruthenium film, the second manganese-ruthenium film, and the third manganese-ruthenium film, the substrate is maintained at a temperature of less than or equal to about 450° C.

15. The method of claim 13, wherein the conductive surface of the bottom of the opening comprises one or more of copper (Cu), cobalt (Co), or tungsten (W).

16. The method of claim 13, wherein forming first manganese-ruthenium film, the second manganese-ruthenium film, and the third manganese-ruthenium film comprises sequential exposure to the metal precursor and a reducing agent.

17. The method of claim 16, wherein the reducing agent comprises one or more of hydrogen (H₂), ammonia (NH₃), oxygen (O₂), hydrocarbon compounds, or hydrogen incorporated compounds.

18. An electronic device comprising
a substrate having a feature formed in a first surface, the feature extending into the substrate from the first surface and having a sidewall with a dielectric surface and a bottom with a conductive surface;
a manganese-ruthenium film in the bottom of the feature on the conductive surface; and
a conductive material on the manganese-ruthenium film filling the feature to form a via.

19. The electronic device of claim 18, wherein the conductive material and the conductive surface independently comprise one or more of copper (Cu), cobalt (Co), tungsten (W), or ruthenium (Ru).

20. The electronic device of claim 18, wherein the dielectric surface comprises one or more of oxides, carbon doped oxides, porous silicon dioxide (SiO₂), silicon oxide (SiO), silicon nitride (SiN), carbides, oxycarbides, nitrides, oxynitrides, oxycarbonitrides, carbonitrides, polymers, phosphosilicate glass, fluorosilicate (SiOF) glass, or organosilicate glass (SiOCH).
